(19) United States
(12) Patent Application Publication
(10) Pub. No.: US 2010/0027807 A1
(43) Pub. Date: Feb. 4, 2010

(54) METHOD AND APPARATUS FOR ADJUSTING AUDIO VOLUME TO PREVENT HEARING LOSS OR DAMAGE

(76) Inventor: Yun Ho Jeon, Seoul (KR)

Correspondence Address: KNOBBE MARTENS OLSON & BEAR LLP, 2040 MAIN STREET, FOURTEENTH FLOOR, IRVINE, CA, 92614, US

(21) Appl. No.: 12/303,539

(22) PCT Filed: Oct. 8, 2007
(86) PCT No.: PCT/KR2007/004899

§ 371 Date: Sep. 15, 2009

(30) Foreign Application Priority Data
Oct. 30, 2006 (KR) 10-2006-0105650

(51) Int. Cl. H03G 3/20; H04R 1/10

(52) U.S. Cl. 381/74; 381/108

(57) ABSTRACT

Techniques and apparatus for limiting a sound pressure level produced by an audio output device driven by an audio player. During play, the audio player monitors the current sound pressure level of the audio output device, and in response thereto limits the sound pressure level by controlling an output level of audio signals it generates so as to reduce hearing loss caused by excess volume.

### TECHNICAL FIELD

The present disclosure relates to audio players, and more particularly to an audio reproduction apparatus for adjusting the volume of an audio players.

### BRIEF DESCRIPTION OF THE DRAWINGS

The present disclosure may best be understood by reference to the following detailed description when considered in connection with the accompanying drawings.

FIG. 1 shows a schematic diagram of one embodiment of an audio player in accordance with the present disclosure.

FIG. 2 shows a more detailed schematic diagram of one embodiment of the volume control device of the audio player in accordance with the present disclosure.

FIG. 3 illustrates a schematic diagram of one embodiment of the audio output device connector for use with an exemplary jack plug of an audio output device in accordance with the present disclosure.

FIG. 4 shows a schematic diagram of one embodiment of an adapter configured to connect the audio player and a conventional three-conductor jack plug of an audio output device in accordance with the present disclosure.

FIG. 5 illustrates a flow chart of one embodiment of a method for adjusting a volume of audio signals to an audio output device by the audio player in accordance with the present disclosure.

FIG. 6 shows a schematic block diagram of one embodiment of an audio player that allows a manual and/or automatic input of sensitivity data without using an external conductor and/or resistor in accordance with the present disclosure.

FIG. 7 shows an embodiment of an audio player connected to an audio output device having an IC chip in accordance with the present disclosure.

FIG. 8 shows an embodiment of audio output device capable of adjusting a volume of audio signal from an audio player in accordance with the present disclosure.

### BACKGROUND

Recently, portable audio systems, such as CD, MP3, MD, and media players, have become popular, especially due to the advent of technologies that made such systems smaller and more powerful at the same time. These portable audio systems typically play, for example, music via audio output devices such as earphones, headphones and the like. Such output devices provide a convenient means for enjoying music without disturbing others in proximity.

While the popularity of portable audio systems has soared recently, many users have also become accustomed to listening to loud music for a long period of time with headphones or earphones. Listening to loud music at a high volume for a prolonged period of time, however, may lead to temporary, or even permanent, hearing loss or damage.

In a noisy environment, listeners tend to set the volume level higher to block out ambient noise. For example, in excessively noisy environments such as subway stations, airplanes and crowded areas, users typically set the audio output volume to a sufficiently high level to overcome the background noise. Since the loudness level of sound perceived by a listener is related to the ambient noise level and the sound pressure level (SPL) of sound output devices, listening to music at a high volume setting with loud ambient noise may ultimately lead to hearing damage or loss.

To overcome the ambient noise problem, noise canceling headphones have been developed to reduce background noise to some degree. While such headphones reduce the ambient noise somewhat, they typically do not allow automatic adjustment of the volume level set by the user to reduce the risk of hearing damage or loss. In addition, these headphones tend to be bulky, inconvenient and expensive, and thus, inappropriate as portable audio devices.

As a further solution to the above problems, manufacturers of portable audio players have developed safety circuitry which warn the user or limit the output volume when the volume reaches a dangerously high level. Such safety circuitry limits the output volume by limiting the output electric power of the audio player within an acceptable level to allow the user to listen to music without serious damage to hearing. Such a solution, however, may not be preferred by consumers who would rather control the volume level themselves. Further, simply limiting the output electric power of the audio player may not be effective for different headphones with varying sensitivity (defined as the sound pressure level produced at a specific power input). Indeed, since hearing loss is related to the output sound pressure level provided and the exposure period, limiting the output electric power of the audio player may not directly correlate with preventing hearing damage or loss.

### SUMMARY

The present disclosure is directed to an audio player capable of adjusting an audio volume outputted through an audio output device based on a sound pressure level of the audio output device. The audio player monitors the sound pressure level of the audio output device by monitoring the output level of the audio signal provided to the audio output device in combination with the sensitivity value of the audio output device. The audio player controls the audio volume (i.e., sound pressure level produced by the audio output device) based on the monitored sound pressure level.

In one embodiment, an audio player includes a volume adjustment unit, an output adapter, and a volume limiting unit. The volume adjustment unit is configured to control an output level of an output audio signal. The output adapter is configured to provide the output audio signal to an audio output device. The volume limiting unit is configured to limit an audio volume produced at the audio output device by adjusting the volume adjustment unit.

In another embodiment, an audio player includes a volume adjustment unit and an output adapter. The volume adjustment unit is configured to control an output level of an output audio signal. The output adapter is configured to provide the output audio signal to an audio output device. The audio player is configured to limit an audio volume produced at the audio output device by monitoring a sound pressure level of the audio output device.

In yet another embodiment, an audio output device for a media player includes an input adapter, a speaker, and a volume control unit. The input adapter is configured to receive an audio signal. The speaker is configured to covert the audio signal into sound. The volume control unit is configured to monitor the audio signal and to control an output level of the audio signal provided to the speaker.

In a further embodiment, a method for controlling an output volume of a media player comprises: (i) determining an output level of an audio signal provided to an audio output device; (ii) monitoring a sound pressure level produced by the audio output device driven by the media player based upon the output level; and (iii) controlling the output level of the audio signal in response to monitoring the sound pressure level.

In still another embodiment, a computer-readable medium stores instructions that when executed by a media player cause the media player to perform a method for controlling an output volume of the media player. The method comprises: (i) monitoring a sound pressure level produced by an audio output device coupled to the media player in response to an output audio signal generated by media player; and (ii) controlling an output level for the output audio signal in response to monitoring the sound pressure level.

### DETAILED DESCRIPTION

In the following description, numerous specific details are set forth. It will be apparent, however, that these embodiments may be practiced without some or all of these specific details. In other instances, well known process steps have not been described in detail in order not to unnecessarily obscure the present disclosure.

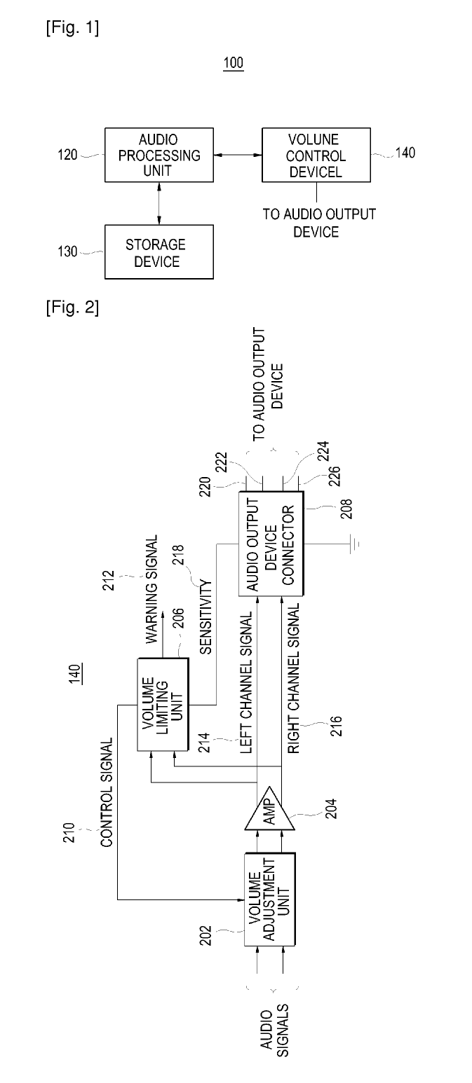

FIG. 1 shows one embodiment of an audio player. The audio player 100 includes an audio processing unit 120, a storage device 130 and a volume control device 140. The audio player 100 may be any media player capable of playing media files with audio contents, such as a portable CD player, a cassette player, an MD player, a portable media player, an MP3 player, an MP3 cellular phone, and the like, that can be connected to an audio output device, such as earphones, headphones, and the like. The audio player 100 stores various media files, such as music files, video files, audio files, and the like, in the storage device 130, which can be provided within the audio player 100 or removably connected to the audio player 100 and includes a memory card, cassette tape, compact disk, optical disk, and the like.

The media files from the storage device 130 are provided to the audio processing unit 120, which is a processor configured to process and play the media files. In playing the media files, the audio portion of the files is processed to generate audio signals. Specifically, the audio processing unit 120 generates audio signals from the media files and transmits the audio signals to the volume control device 140. The volume control device 140 controls the output level (i.e., power) of the audio signals based on volume levels configurable by user input and also functions to limit the volume of the audio output device based on information on the audio output device connected to the audio player 100. The audio signals are then provided to an audio output device, such as a speaker, an earphone, a headphone, and the like, which converts the signals to sound.

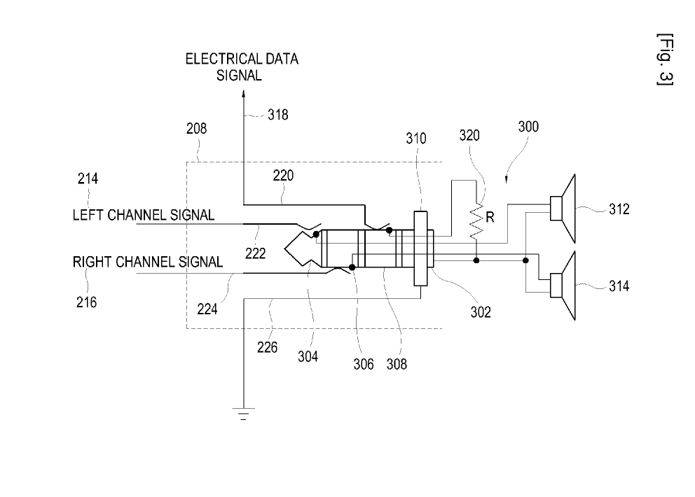

FIG. 2 shows a more detailed schematic diagram of one embodiment of the volume control device 140 of the audio player 100. The volume control unit 140 includes a volume adjustment unit 202, an amplifier 204, an audio output device connector 208, and a volume limiting unit 206. The volume adjustment unit 202 receives the audio signals from the audio processing unit 120 for controlling the output level of the audio signals. The audio signals includes left and right channel signals 214 and 216 respectively, each of which is delivered to the left and the right channels in an audio output device in case of a typical stereo system. The volume adjustment unit 202 controls the output level by adjusting the output electric power to be delivered to the amplifier 204 and ultimately to the audio output device in response, for example, to the user's operation of a volume adjustment key or knob to set a volume level on the audio player 100.

For amplifying the input audio signals, the amplifier 204 has a constant amplifying coefficient (e.g., gain) indicating a ratio between the electric power of a signal input to the amplifier 204 and the electric power of the signal amplified by the amplifier 204.

According to the amplifying coefficient, the amplifier 204 receives and amplifies the left and the right channel signals 214 and 216 from the volume adjustment unit 202 to a level audible to human ears. The amplified left and right channel signals are then provided to the audio output device connector 208 in the form of a socket, which provides an interface to an audio output device equipped with a jack plug that can be inserted into the audio output device connector 208. In addition, the amplifier 204 provides the amplified signals to the volume limiting unit 206 for determining the output electrical power provided to the audio output device via the audio output device connector 208.

The audio output device connector 208 is configured to include one or more conductors, such as lines, contact portions, and the like, for providing electrical contact with corresponding conductors in the jack plug of the audio output device. In contrast to conventional audio output device connectors, which typically have three conductors (two conductors for the left and right channel signals, and a ground conductor), the audio output device connector 208 is configured with four conductors: two conductors 222 and 224 for the left and right channel signals 214 and 216 respectively, a ground conductor 226, and an additional conductor 220. The additional conductor 220 in the audio output device connector is configured to provide electrical data signal 218 indicating one or more electrical characteristics (e.g., sensitivity and/or impedance data) of the audio output device to the volume limiting unit 206. The electrical characteristics data may include, for example, either or both sensitivity and impedance of the audio output device in contact with the conductor 220.

Based on the received electrical data signal and output electric power delivered to the audio output device, the volume limiting unit 206 determines and monitors the sound pressure level of the audio output device. In the case of sensitivity data, the sensitivity of a headphone is defined as the sound pressure level produced at a specific input electric power and may be represented as the number of dB of actual sound pressure level produced by the headphone with 1 mW of input electric power. Thus, the sensitivity of headphones can be determined by applying 1 mW to the headphones and measuring the sound pressure level generated at the earpiece using a dummy head with built-in microphones. Audio output device manufacturers typically specify sensitivity ratings for their products, usually in a manual packaged with the products. In accordance with one embodiment, the sensitivity is recorded or stored in the audio output device at the manufacturing stage and is detected by the audio player 100 when the jack plug of the audio output device is inserted to contact the conductor 220 in the audio output device connector 208 of the audio player 100.

With reference to FIG. 2, the volume limiting unit 206 determines the output electric power delivered to the audio output device. The output electric power can be determined in various ways by using hardware, software or a combination thereof. For example, the output electric power may be determined by measuring a voltage and a current associated with the audio signals provided to the volume limiting unit 206 from the amplifier 204. Each envelope of the left and the right channel signals represents a voltage level associated with the channel signals so that the voltage value can be directly obtained by detecting the envelope of the channel signals. To determine the current associated with the channel signals, a resistor with a known small resistance value may be inserted between the amplifier 204 and the audio output device and the voltage over the resistor can be measured. Thus, the volume limiting unit 206 may determine the output electric power by multiplying the voltage and the current measured to thereby obtain the sound pressure level. On the other hand, if the sensitivity or other parameter is defined to be the ratio between the sound pressure level at a specific voltage level and not an output electric power, the sound pressure level can be directly obtained from the sensitivity and the voltage, with a little margin of error due to the variation of the impedance versus frequency.

In the case where the electrical data is an impedance value of an audio output device, the volume limiting unit 206 may determine the output electric power by using the voltage and the impedance value of the audio output device without knowing the current value. The impedance value can be obtained by various methods, for example by including the impedance value in the electrical data from the audio output device or by manually inputting the impedance value through an input device (not shown) of the audio player 100. In one embodiment, the amplifier 204 typically includes a non-zero, but known impedance so that the output electric power can be determined by using the impedance value of the audio output device taking into account the amplifier's known impedance.

Once the output electric power delivered to the audio output device has been determined, the volume limiting unit 206 determines the sound pressure level of the audio output device from the electrical data and the output electric power. For example, the sound pressure level may be estimated based upon the output electric power and the sensitivity with minor unit change between a dB scale and a normal scale. In one embodiment, since the sound pressure level is proportional to the current through a voice coil of the audio output device and the current is related with the output electric power in root square, the sound pressure level is calculated based upon the root square value of the output electric power.

The volume limiting unit 206 continuously monitors the sound pressure level of the audio output device during operation and limits the sound pressure level based on estimates of the degree of hearing loss or damage that may result from the monitored sound pressure level of the audio output device over a period of time. To model the degree of hearing loss, the volume limiting unit 206 monitors the time period the user is exposed to the sound pressure level, since hearing loss or damage can be caused by a one-time exposure to loud sound as well as by continuous exposure to sounds at various sound levels over an extended period of time. Thus, the volume limiting unit 206 integrates (e.g., averages) the sound pressure level for various time periods and monitors whether the integrated sound pressure level during each of the time periods, i.e., the time average value of the sound pressure level, is more than or equal to a threshold sound pressure level for each time period. When the integrated sound pressure level for a time period exceeds a specified level, the volume limiting unit 206 generates and provides the control signal 210 to the volume adjustment unit 202 to control or limit the volume of the audio output device by adjusting the output electric power delivered to the audio output device. The volume limiting unit 206 may also generate a warning signal 212 to alert a user by generating an audible warning or displaying a warning message on a displaying unit (not shown) of the audio player 100 so that the user may limit the volume manually. In one embodiment, Table 1 provides some examples of integrated sound pressure levels and exposure time periods that trigger the volume limiting unit 206 to generate the control signal and/or warning signal 212.

TABLE 1

| Integrated SPL (dB) | Exposed time period | |
|---|---|---|
| 85 | 8 | hours |
| 88 | 4 | hours |
| 91 | 2 | hours |
| 94 | 1 | hour |
| 97 | 30 | minutes |
| 100 | 15 | minutes |
| 103 | 7.5 | minutes |
| 106 | 3.75 | minutes (<4 minutes) |
| 109 | 1.875 | minute (<2 minutes) |
| 112 | 0.9375 | minute (<1 minutes) |
| 115 | 0.46875 | minute (<30 seconds) |

As can be seen in Table 1 above, for every 3 dB over 85 dB of the SPL, the allowable exposure time, which does not generate a hearing loss index indicating a danger of deafness, is cut in half. The volume limiting unit 206 generates a control signal 210 based upon the hearing loss index and sends the control signal 210 to the volume adjustment unit 202 to control or limit the output level of the audio signal by adjusting the output electric power delivered to the audio output device. The volume limiting unit 206 may also generate a warning signal 212 to alert a user by generating an audible warning or displaying a warning message on a displaying unit (not shown) of the audio player 100 so that the user may limit the volume manually. For example, the volume limiting unit 206 may transmit a control signal 210 to the volume adjustment unit 202 or generate the warning signal 212, when the integrated SPL in the left column of Table 1 has maintained for more than or equal to the exposed time period in the right column of Table 1. In this manner, prolonged exposure of the user to loud sound can be prevented. The volume limiting unit 206 may be implemented in a form of hardware and software and a combination thereof.

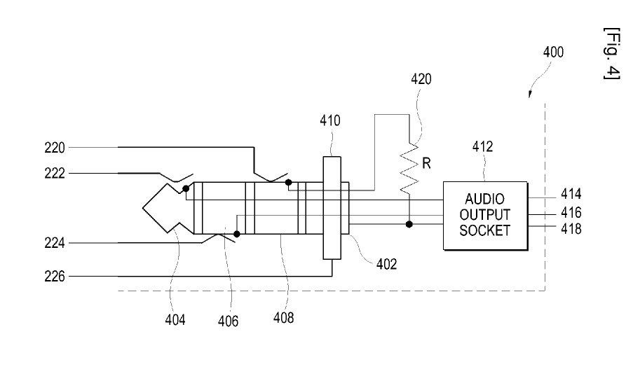

FIG. 3 illustrates a schematic diagram of one embodiment of the audio output device connector 208 for use with an exemplary jack plug 302 of an audio output device 300. The audio output device 300 includes the jack plug 302 coupled to left and right audio speakers 312 and 314, which convert the left and right channel signals into sound. The jack plug 302 includes four conductors: 304, 306, 308 and 310: a left and a right channel conductors 304 and 306 to deliver the left and right channel signals 214 and 216, respectively, to the left and right audio speakers 312 and 314, a ground conductor 310 to provide a connection to the ground, and an additional conductor 308 for providing electrical data signal associated with the audio output device 300. The four conductors 304, 306, 308, and 310 are configured to contact corresponding conductors 222, 224, 220, and 226, respectively, of the audio output device connector 208. The left and the right channel signals 214 and 216 are transmitted to the left and the right speakers 312 and 314 of the audio output device 300 via the conductors 304 and 306, respectively. In contrast to conventional three-conductor jack plug for a stereo audio output devices which employ three conductors, the jack plug 302 in this embodiment provides an extra conductor by dividing the ground conductor of the conventional three-conductor jack plug into two conductors: the ground conductor 310 and the extra conductor 308.

Between the extra conductor 308 and the ground conductor 310 of the audio output device 300, a resistor 320 is provided with a predetermined resistance value R, which corresponds to the sensitivity of the audio output device 300. In accordance with one embodiment, the sensitivity of the audio output device 300 is preferably measured during the product manufacturing stage, since each of the products, i.e., the audio output device 300 may possibly have unique sensitivity value which can be different for every product. The resistance value may be recorded in the audio output device 300 by connecting the resistor 320 having a resistance value corresponding to the sensitivity between the conductors 308 and 310. The resistor 320 can be installed in a circuit of the audio output device 300 at the final assembly stage of the manufacturing process of the audio output device 300.

The volume limiting unit 206 reads the resistance value R of the audio output device 300 to receive the sensitivity of the audio output device 300. In order to read the resistance value R of the resistor 320, for example, the audio player 100 may measure a voltage of a line 318 contacting the conductor 308 and a current flowing along a circuit line connected to the line 318 coupled to the conductor 308. In this manner, the volume limiting unit 206 obtains the sensitivity of the audio output device 300 to estimate the sound pressure level of the audio output device 300.

The audio output device 300 in accordance with the present disclosure covers various types of devices named as headphones, earphones, earbuds, stereophones, canalphones, or headsets, but without limitation thereto. The audio output device 300 includes any pair of transducers that receive an audio signal from a media player placed in close proximity to the ears to convert the audio signal into audible sound waves, without limitation to specific types of audio output devices.

The audio player 100 in one embodiment may also be used with an audio output device with a conventional three-conductor jack plug. In this case, the resistance value R of such audio output device is nearly zero since there is no extra conductor and the audio player 100 may use a default sensitivity value as the sensitivity of the audio output device. For use with a conventional audio output device that does not have the extra conductor, an adapter having an extra conductor may be inserted between the audio player and the audio output device. The user can select an adapter which corresponds to the sensitivity of the audio output device. The manufacturers of the audio output device 300 may sell such an adapter as an accessory to the audio output device 300.

FIG. 4 shows a schematic diagram of one embodiment of an adapter 400 configured to connect the audio player 100 and a conventional three-conductor jack plug of an audio output device. Similar to the jack plug 302 in FIG. 3, the adapter 400 includes an audio output socket 412 and a plug 402 configured with four conductors 404, 406, 408 and 410. The plug 402 of the adapter 400 is adapted to be inserted into the audio output connector 208 of the audio player 100 in FIG. 2 such that the conductors 404, 406, 408 and 410 come in contact with corresponding conductors 222, 224, 220 and 226, respectively. Similar to the audio output device 300 in FIG. 3, a resistor 420 with a resistance value R is provided between the conductor 408 and the ground conductor 410. The resistance value R of the resistor 420 is preconfigured according to the sensitivity of the audio output device, which is adapted to be inserted into the audio output socket 412. The sensitivity of the audio output device is measured during the manufacturing process of the adapter 400 and the corresponding three-conductor audio output device and the resistor 420 having a resistance value corresponding to the measured sensitivity is provided between the conductors 408 and 410.

For use with a conventional three-conductor audio output device, the audio output socket 412 includes three output conductors or lines 414, 416 and 418 that can be connected to the jack plug of the conventional three-conductor audio output device. The output conductors or lines 414 and 416 deliver the left and the right channel signals to the conventional audio output device while the output conductor or line 418 provides a ground connection to the conventional audio output device. In this manner, the conventional three-conductor audio output device can be connected to the audio player 100 in FIG. 2 via the adapter 400 incorporating the resistor R indicating the sensitivity of the conventional audio output device.

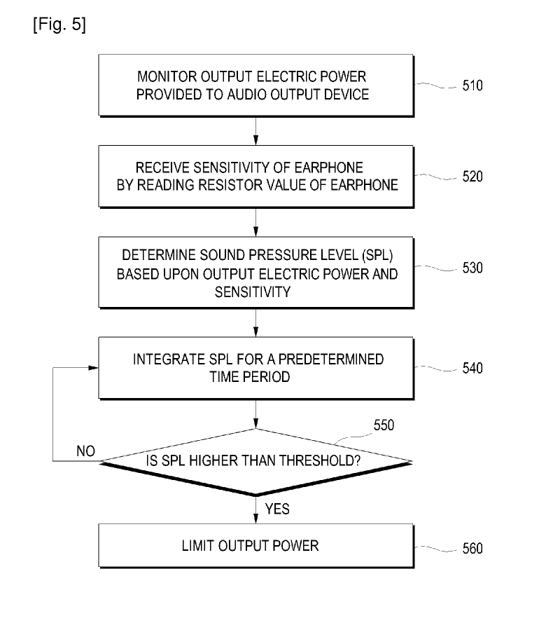

FIG. 5 illustrates a flow chart of one embodiment of a method for adjusting an output level of audio signals to an audio output device by the audio player 100. Initially in operation 510, the audio player 100 outputs audio signals and monitors the output electric power delivered from the audio player 100 to the audio output device. As described above, the output electric power of the audio player 100 can be determined by measuring and multiplying the voltage value and the current value associated with the audio signals provided to the audio output connector 208. Alternatively, given the impedance of the audio output device 300, the audio player 100 determines the output electric power by using the voltage and the impedance value.

Then, in operation 520, the audio player 100 receives sensitivity value of the audio output device, for example, by reading a resistor placed in the audio output device, which may be connected to the audio player 100 directly. Alternatively, a three-conductor audio output device may be connected to the audio player 100 via the adapter 400 having a resistor indicating the sensitivity of the audio output device connected to the adapter 400. In operation 530, the audio player 100 determines the sound pressure level (SPL) of the audio output device by using the output electric power and the sensitivity obtained in operations 510 and 520.

In operation 540, while monitoring the sound pressure level provided to the audio output device via audio output connector, the audio player 100 integrates the sound pressure level for a predetermined time period. If the audio player 100 determines that the sound pressure level is not higher than a predetermined threshold value in operation 550, it proceeds back to operation 540 to continue integrating the sound pressure level. If, however, the audio player 100 determines that the sound pressure level is higher than the predetermined threshold value in operation 550, it provides the control signal 210 to the volume adjustment unit 202 to limit the electric output power. In this operation, the volume adjustment unit 202 reduces the electric output power provided to the amplifier. Optionally, the audio player 100 may also display or issue a warning sign to alert the user that the volume should be lowered.

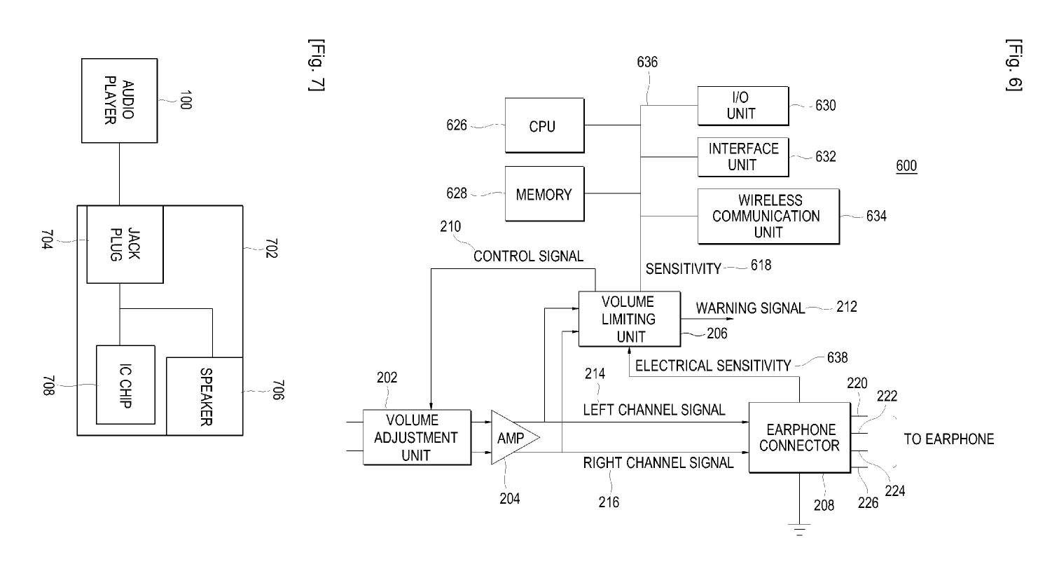

Although the audio player 100 receives the sensitivity value from audio output devices, the audio player 100 may receive the sensitivity value of audio output devices manually from the user or automatically via a computer. FIG. 6 shows a schematic block diagram of one embodiment of an audio player 600 that allows a manual and/or automatic input of sensitivity data without using an external conductor and/or resistor. The audio player 600 includes a CPU 626, a memory 628, an I/O unit 630, an interface unit 632, and a wireless communication unit 634, which are coupled to a bus 636 to provide sensitivity data of an audio output device to the volume limiting unit 206. In one embodiment, the audio player 600 allows the user to input electrical specification data 618 (e.g., sensitivity or impedance of the audio output device) as provided in a manual or a handbook related to the audio output device via the I/O unit, such as keypad, keyboard, and the like. In this arrangement, the audio player 600 may provide an appropriate menu for the user to input the sensitivity value of the audio output device under the control of the central processing unit (CPU) 626. The electrical specification data 618 is then stored in the memory 628, which is provided to the volume limiting unit to control output volume level.

In an alternate embodiment, the interface unit 632 provides a connection to an external device, such as a personal computer, to receive the electrical data of the audio output device from the external device. The interface unit 632 may also include a communication module for a short range communication, such as Bluetooth, Zigbee, the infrared or RF communication as well as a cable connection such as a universal serial bus (USB). The user may input the electrical data 618 of the audio output device by using an input device of the computer (e.g., a keyboard) and download the information into the memory 628 such that the audio player 600 may use the information in determining the sound pressure level of the audio output device. For receiving the electrical data, the external computer and the audio player 600 may execute an application program, which may be provided by the manufacturer of the audio output device.

In another embodiment, the electrical data 618 may be inputted from a manufacturer's server via a remote connection. For example, the user of the audio player 600 may log on to an Internet website provided by the manufacturer and click on a menu to download the electrical specification information, such as sensitivity, impedance, and the like of an audio output device onto the audio player 600 via the interface unit 632. The downloaded electrical specification data is then stored in the memory 628, such as DRAM, flash memory, and the like. The volume limiting unit 206 reads the stored electrical data 618 to estimate the sound pressure level as described above.

The wireless communication module 634 allows the audio player 600 to communicate with a mobile communication network, such as GSM, CDMA, and the like. For example, a cellular phone having a functionality of MP3 player can be equipped with such a module. In this case, the electrical data 618 is directly downloaded into the memory 628 without necessarily being connected to the external computer via the interface unit 632. For example, the audio player 600 receives a configuration file including all the electrical data of one or more audio output devices from the server of the manufacturer through the mobile communication network by using the wireless communication module 634. The configuration file can be downloaded by the operation of the user in advance or at the time of inserting a specific type of audio output device into the audio player. The user may select to download a specific configuration file of one audio output device or all the audio output devices provided by the manufacturer. The downloaded configuration file is stored into the memory 628 and read by the volume limiting unit 206 to calculate the sound pressure level of the corresponding audio output device. The configuration file includes various types of electrical data, such as sensitivity, impedance, and the like.

Alternatively, the configuration file can be downloaded in a plug-and-play way by detecting the type of the audio output device inserted into the audio output connector 208 when the audio output device is connected to the audio player. To identify the audio output device, the audio output device provides identifying information to the audio player 600 to allow the audio player to detect the type of the audio output device. For example, the resistor 320 in the audio output device 100 in FIG. 3 with four conductors can be selected to indicate the type or model name of the audio output device instead of simply indicating the sensitivity. The audio player 600 detects the type of the audio output device inserted into the audio output connector 208 by reading the resistance value of the resister. The volume limiting unit 206 receives the identifying information (e.g., the model name of the audio output device) and determines whether a configuration file corresponding to the audio output device is stored in the memory 628 or not. If the configuration file is stored in the memory 628 of the audio player 600, the volume limiting unit 206 determines the sound pressure level of the audio output device by using the sensitivity and/or the impedance data in the configuration file.

If the configuration file corresponding to the inserted audio output device is not stored in the memory 628, the user may trigger the audio player 600 to start the process of downloading the configuration file by using the wireless communication unit 634. The audio player 600 may also initiate the downloading process without triggering or inputting activity from the user in such a way that the audio player 600 transmits a request message to the server of the manufacturer via the mobile communication network. After the audio player 600 receives the configuration file, it starts to perform the volume control process as described above.

In one embodiment, the audio output device may include an IC chip (e.g., IC memory chip) for providing the electrical data. FIG. 7 shows an embodiment of an audio player 100 connected to an audio output device 702 having an IC chip 708. The IC chip (e.g., IC memory chip) stores electrical data, such assensitivity, model number, impedance, efficiency, and other information relating to the audio output device 702. The audio output device 702 includes a jack plug 704 configured to provide the electrical data from the IC chip 708 to the audio player 100. The jack plug 704 includes four conductors 304, 306, 308 and 310 of FIG. 3. Among four conductors, two conductors 304 and 306 carry audio data from the audio player 100 to speakers 706 and one conductor 310 provides a ground connection. The conductor 308 is configured to contact the conductor 220 to provide the electrical data from the IC chip 708 to the volume limiting unit 208 in the audio player 100. The audio player 100 may read the characteristic information in the IC chip by using various methods as known to those skilled in the art. The audio player 100 performs the operations to prevent hearing loss or damage as described above with reference to FIGS. 2 to 6.

In another embodiment, the audio player 100 and the audio output device 702 may include a wireless communication capability by employing a digital interface protocol, such as universal serial bus (USB) link, or wireless interface connection, such as BloothTooth, ZigBee, HDMI (high definition multimedia interface), HDCP (high-bandwidth digital contents projection), and the like. In this case, the audio player 100 may communicate with the audio output device 702 via a wireless connection to obtain the electrical data of the audio output device 702. For example, in case of a USB headphone having a digital to analog converter (DAC), the audio player 100 may receive sensitivity data from the audio output device 702 while transmitting the audio data to be played by the audio output device 702.

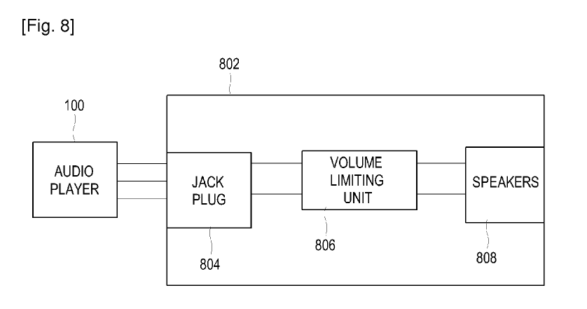

In another embodiment, an audio output device may itself include a volume limiting unit to adjust the sound pressure level of the audio output device. FIG. 8 shows an embodiment of audio output device 802 capable of adjusting an output level of audio signal from an audio player 100. In this case, the audio output device 802 is connected to the audio player 100 having three contacting lines as a conventional audio player. The audio output device 802 includes a jack plug 804 for providing a connection interface to the audio player 100. The jack plug 804 has three conductors, for contact with corresponding conductors in the audio player 100. Among the three conductors, two conductors carry audio data from the audio player 100 to speakers 808 and one conductor provides a ground connection as describe above.

The audio output device 802 includes a volume limiting unit 806 coupled between the jack plug 804 and the speakers 808 for adjusting a sound pressure level to be heard by human ears within a predetermined range. The volume limiting unit 806 performs similar functions to the volume limiting unit 206 described with reference to FIG. 2. In this case, however, the volume limiting unit 806 may directly store and obtain the sensitivity of the audio output device 802. For example, the volume limiting unit 806 measures an input electric power delivered from the audio player 100 by using a voltage and a current associated with audio signals received from the audio player 100. The volume limiting unit 806 also determines a sound pressure level by using the input electric power and the sensitivity. As described above with reference to FIGS. 2 to 5, the volume limiting unit 806 integrates the sound pressure level to control or limit the output level provided to the speakers 808 by adjusting the SPL to be heard by the human ears.

1. An audio player, comprising:
a volume adjustment unit configured to control an output level of an audio signal;
an output adapter configured to provide the audio signal to an audio output device; and
a volume limiting unit configured to limit the output level produced at the audio output device by adjusting the volume adjustment unit.

2. The audio player of claim 1, wherein the volume limiting unit limits the output level based upon a sound pressure level of the audio output device.

3. The audio player of claim 1, wherein the volume limiting unit receives information on an electrical characteristic of the audio output device.

4. The audio player of claim 1, wherein the volume limiting unit determines an electric power associated with the audio signal.

5. The audio player of claim 1, wherein the volume limiting unit generates a control signal which is provided to the volume adjustment unit to limit the output level.

6. The audio player of claim 2, wherein the volume limiting unit integrates the sound pressure level over a period of time; and
adjusts the volume control unit to limit the output level of the audio signal based on predetermined audio exposure limits derived from the integrated sound pressure level.

7. The audio player of claim 6, wherein when the integrated sound pressure level exceeds a predetermined level, the volume limiting unit generates a control signal which is provided to the volume adjustment unit.

8. The audio player of claim 7, wherein the volume adjustment unit controls the output level of the audio signal based on the control signal.

9. The audio player of claim 3, wherein the volume limiting unit monitors a sound pressure level by using the information on the electrical characteristic of the audio output device.

10. The audio player of claim 3, wherein the volume limiting unit is configured to receive the information on the electrical characteristic of the audio output device through the output adapter.

11. The audio player of claim 3, wherein the information on the electrical characteristic is obtained by reading a resistance value of a resistor in the audio output device.

12. The audio player of claim 3, further including an interface unit configured to provide a connection to an external device.

13. The audio player of claim 12, wherein the volume limiting unit is configured to receive the information on the electrical characteristic of the audio output device through the interface unit from the external device.

14. The audio player of claim 1, wherein the audio output device is a headphone.

15. The audio player of claim 1, wherein the audio output device is an earphone.

16. An audio player, comprising:
a volume adjustment unit configured to control an output level of an audio signal; and
an output adapter configured to provide the audio signal to an audio output device,
wherein the audio player is configured to limit the output level produced at the audio output device by monitoring a sound pressure level of the audio output device.

17. The audio player of claim 16, wherein the audio player generates a control signal which is provided to the volume adjustment unit to limit the output level.

18. The audio player of claim 16, wherein the audio player integrates the sound pressure level over a period of time; and
adjusts the volume control unit to limit the output level of the audio signal based on predetermined audio exposure limits derived from the integrated sound pressure level.

19. The audio player of claim 16, wherein the audio player is configured to receive a signal indicating electrical characteristic of the audio output device to limit the output level.

20. The audio player of claim 19, wherein the audio player determines the sound pressure level of the output audio signal based on the signal.

21. The audio player of claim 19, wherein the electrical characteristic includes a sensitivity value of the audio output device.

22. The audio player of claim 19, wherein the signal is obtained by reading a resistance value of a resistor in the audio output device.

23. The audio player of claim 19, wherein the electrical characteristic includes an impedance value associated with the audio output device.

24. The audio player of claim 16, wherein the output adapter includes at least three conductors.

25. The audio player of claim 16, wherein the audio output device is a headphone.

26. The audio player of claim 16, wherein the audio output device is an earphone.

27. The audio player of claim 19, wherein the audio player is configured to receive the signal through the output adapter.

28. An audio output device for a media player, comprising:
an input adapter configured to receive an audio signal;
a speaker configured to covert the audio signal into sound; and
a volume control unit configured to control an output level of the audio signal provided to the speaker based on a sound pressure level produced by the speaker.

29. The audio output device of claim 28, wherein the volume control unit limits the output level produced at the speaker based upon the sound pressure level.

30. The audio output device of claim 28, wherein the audio output device determines the sound pressure level of the audio signal by using a sensitivity value of the audio output device.

31. The audio output device of claim 28, wherein the audio output device integrates the sound pressure level over a period of time; and
adjusts the volume control unit to limit the output level of the audio signal based on predetermined audio exposure limits derived from the integrated sound pressure level.

32. The audio output device of claim 30, further comprising:
a memory configured to store the sensitivity value of the audio output device.

33. The audio output device of claim 30, wherein the sensitivity value is obtained by reading a resistance value of a resistor in the input adapter.

34. The audio output device of claim 28, wherein the input adapter includes at least three conductors.

35. The audio output device of claim 28, wherein the audio output device is a headphone.

36. The audio output device of claim 28, wherein the audio output device is an earphone.

37. A method for controlling an audio volume of a media player, comprising:
determining an output level of an audio signal provided to an audio output device;
monitoring a sound pressure level produced by the audio output device driven by the media player based upon the output level; and
controlling the output level of the audio signal in response to monitoring the sound pressure level.

38. The method of claim 37, wherein the output level is limited based upon estimates of the degree of hearing loss that results from the monitored sound pressure level of the audio output device.

39. The method of claim 37, wherein the operation of monitoring the sound pressure level comprises determining whether the sound pressure level exceeds a predetermined sound pressure level.

40. The method of claim 39, wherein the operation of controlling the output level of the audio signal comprises, if the sound pressure level exceeds the predetermined sound pressure level, reducing the output level of the audio signal.

41. The method of claim 37, further comprising:
receiving an electrical signal representing an electrical characteristic of the audio output device.

42. The method of claim 41, wherein the sound pressure level is monitored based upon the output level of the audio signal in combination with the electrical characteristic of the audio output device.

43. The method of claim 37, wherein the sound pressure level is integrated over a period of time and the output level of the audio signal is limited based on predetermined audio exposure limits derived from the integrated sound pressure level.

44. The method of claim 37, further comprising:
generating a warning signal for a user.

45. The method of claim 41, wherein the electrical characteristic comprises a sensitivity value of the audio output device.

46. The method of claim 41, wherein the electrical signal is obtained by reading a resistance value of a resistor in the audio output device.

47. The method of claim 41, wherein the electrical signal is obtained from an external device connected to the media player.

48. The method of claim 37, wherein the audio output device is a headphone.

49. The method of claim 37, wherein the audio output device is an earphone.

50. A computer-readable medium storing instructions that when executed by an media player cause the media player to perform a method for controlling an output volume of the media player, the method comprising:
monitoring a sound pressure level produced by an audio output device coupled to the media player in response to an output audio signal generated by media player; and
controlling an output level for the output audio signal in response to monitoring the sound pressure level.

51. The computer-readable medium of claim 50, wherein the operation of monitoring the sound pressure level comprises determining whether the sound pressure level exceeds a predetermined sound pressure level.

52. The computer-readable medium of claim 51, wherein the operation of controlling the output level comprises, if the sound pressure level exceeds the predetermined sound pressure level, adjusting the output level for the output audio signal downward.

53. The computer-readable medium of claim 50, wherein the sound pressure level is integrated over a period of time and the output level of the audio signal is limited based on predetermined audio exposure limits derived from the integrated sound pressure level.

54. The computer-readable medium of claim 50, wherein the method further comprising:
receiving input data indicating an electrical characteristic of the audio output device.

55. The computer-readable medium of claim 54, wherein the sound pressure level is monitored based upon the output level of the audio signal in combination with the electrical characteristic of the audio output device.

56. The computer-readable medium of claim 47, wherein the method further comprising:
generating a warning signal for a user.

57. The computer-readable medium of claim 53, wherein the input data includes a sensitivity value of the audio output device.

58. The computer-readable medium of claim 50, wherein the audio output device is a headphone.

59. The computer-readable medium of claim 50, wherein the audio output device is an earphone.
